(19) United States
(12) Patent Application Publication
(10) Pub. No.: US 2017/0316921 A1
(43) Pub. Date: Nov. 2, 2017

(54) VHF Z-COIL PLASMA SOURCE

(71) Applicant: RETRO-SEMI TECHNOLOGIES, LLC, Beverly, MA (US)

(72) Inventors: Dong-Soo KIM, Yong In-Si (KR); Min-Su JOO, Youn In-Si (KR)

(21) Appl. No.: 15/485,830

(22) Filed: Apr. 12, 2017

Related U.S. Application Data
(60) Provisional application No. 62/329,494, filed on Apr. 29, 2016.

(51) Int. Cl. H01J 37/32; H01L 21/67; H01L 21/687

(52) U.S. Cl. CPC H01J 37/3211; H01L 21/68792; H01J 37/3244; H01L 21/67069; H01J 2237/334

(57) ABSTRACT

A VHF Z-coil semiconductor processing plasma source uses Inductively Coupled Plasma (ICP) and has a Z-shaped coil wound about a chamber in two interconnected turns. High frequency RF electric power of from 40 MHz to 120 MHz is supplied by a power source to the coil. A process gas introduced into the chamber is energized by the coil and generates plasma ions of high density suitable for semiconductor dry etching.

### STATEMENT REGARDING FEDERALLY SPONSORED RESEARCH OR DEVELOPMENT

n/a

### BACKGROUND OF THE INVENTION

In general, plasma reaction sources for plasma dry etching processes are classified as Capacitive Coupled Plasma (CCP) sources or Inductively Coupled Plasma (ICP) sources.

In CCP type plasma reaction sources, ion flux energy in a plasma chamber increases in inverse proportion as the applied power frequency decreases, and the ion density increases in proportion as the frequency increases, when same RF electric power is applied thereto.

In contrast, ICP type plasma reaction sources have a high release area in which release of a process gas occurs abruptly and a low release area in which the release of a process gas does not occur abruptly as RF electric power increases in each. The two areas have different physical characteristics. Specifically, the low release area of an ICP device performs in a manner similar to a CCP type plasma reaction device. However, in the ICP device high release area, when RF electric power increases, the intensity of ion energy abruptly decreases as a lower frequency is applied to a lower electrode.

Plasma dry etching processes include insulation film (oxide) etching and poly/metal etching.

CCP type sources, having a narrow gap to which multiple frequency RF electric power is applied, are mainly used as plasma reaction sources for insulation film etching where physical etchings are performed. While the CCP type plasma reaction device provides an advantage of generating ions of high energy using a high electric field, it can also cause process chamber damage due to ion impact, arcing due to a high plasma potential, relatively low plasma ion density, low chamber cleaning cycle efficiency due to release issues, and a costly and complex hardware design for high frequency electric power.

In contrast to insulation film etching, an ICP type device is mainly used in poly/metal etching where chemical etchings are typically performed. This is because the ICP type plasma reaction device can independently control ion density and ion energy, can easily generate plasma of high density over a large area at a low pressure, can sufficiently perform etching even with low ion energy, and thus can avoid damage to constituent hardware.

Currently, the frequency of RF electric power applied to ICP type plasma reaction sources is 13.56 MHz or 27.12 MHz. The frequency of applied electric power significantly influences plasma ion density; plasma ions of high density are obtained as the frequency increases. However, RF electric power of a higher frequency cannot be applied to the currently employed plasma reaction sources due to limits in the structure and various parameters thereof.

Accordingly, the ability to apply a higher frequency electric power in an ICP type plasma reaction device, compared to frequencies currently used, would significantly improve ion density and thus would improve the efficiency of the etching process.

### BRIEF SUMMARY OF THE INVENTION

The presently disclosed innovation has been made in an effort to solve the above-mentioned problems. One object of the present disclosure is to provide an ICP type plasma device which can use RF electric power of a frequency higher than that of an existing plasma device.

Another object of the present disclosure is to provide an ICP type plasma device by which a density of plasma ions is further improved as compared with an existing plasma device.

The present disclosure relates to a plasma reaction source for semiconductor processing, and more particularly, to a VHF Z-coil plasma source that can take the form of a coil surrounding a chamber for applying high frequency Radio Frequency (RF) electric power to provide plasma ions of high density, enabling an improvement in semiconductor processing performance and productivity.

According to an aspect of the present disclosure, there is provided a Very High Frequency (VHF) Z-coil plasma source for generating and injecting plasma using Inductively Coupled Plasma (ICP), the VHF Z-coil plasma source comprising a chamber for receiving a process gas to generate plasma and inject the generated plasma, a Z-shaped coil wound on the chamber in two turns, and a high frequency RF power source for generating electric power of 40 MHz to 120 MHz to be applied to generate the plasma.

The chamber is comprised of vertically aligned portions, from the top down, including a mixing zone for mixing the process gas, a generation zone for generating the plasma, an acceleration zone for accelerating the plasma, and a diffusion zone for diffusing the plasma. The first horizontal turn of the coil is disposed about the generation zone and the second horizontal turn is disposed about the acceleration zone. One or more diffusion plates for efficiently diffusing the process gas are disposed at lower portions of each of the mixing zone and the diffusion zone. In one instance, the coil has the shape of a lower-case “g” when viewed in elevation.

One or more supply pipes for supplying the process gas are connected to an upper portion of the chamber, and to the mixing zone in particular. The chamber has a cylindrical shape, with the diameter thereof ranging from 5 cm to 10 cm, and the height thereof ranging from 10 cm to 15 cm.

The chamber is formed of at least one of ceramic, quartz, silicon carbide (SiC) and sapphire. The diffusion plate(s) is formed of at least one of ceramic, quartz, silicon carbide (SiC), sapphire, and aluminum.

A chuck on which a semiconductor wafer may be disposed is disposed below the chamber, whereby the distance between the chamber and a wafer disposed on the chuck may range from 3 cm to 10 cm. A length of the chuck may range from 20 cm to 40 cm.

According to the presently disclosed innovation, a coil having a specific shape is coupled to the chamber for generating plasma. RF electric power of a frequency that is higher than that of an existing plasma device is applied thereto. Plasma ions of improved density generated by the presently disclosed source can be used in a dry etching process.

In addition, according to the presently disclosed innovation, the efficiency of a dry etch process is further improved by arranging diffusion plates in the interior of the chamber. The process gas and plasma are thus efficiently diffused.

It should be understood that different embodiments of the present disclosure, including those described under different aspects, are meant to be generally applicable to all aspects of the disclosure. Any embodiment may be combined with any other embodiment unless inappropriate. All examples are illustrative and non-limiting. The foregoing description of a plasma device is illustrative of a first embodiment; other embodiments may differ in shape, size, and composition.

### BRIEF DESCRIPTION OF THE SEVERAL VIEWS OF THE DRAWINGS

Other features and advantages of the present invention will be apparent from the following detailed description of the invention, taken in conjunction with the accompanying drawings of which:

FIG. 1 is a perspective view of a VHF Z-coil plasma source according to an embodiment of the presently disclosed invention;

FIG. 2 is a perspective view of a VHF Z-coil plasma source according to another embodiment of the presently disclosed invention;

FIG. 3 is a projective perspective view of a plasma chamber for use in the embodiments of FIGS. 1 and 2;

FIG. 4 is a projective front view of the plasma source of FIG. 1; and

FIG. 5 is a projective perspective view illustrating the principle of a diffusion plate variously disposed within a plasma chamber according to the presently disclosed invention.

### DETAILED DESCRIPTION OF THE INVENTION

This application claims priority of U.S. Provisional Patent Application No. 62/329,494, filed Apr. 29, 2016, the entirety of which is hereby incorporated by reference.

As used herein, etching refers to corroding surfaces, for example, of metals, ceramics, semiconductors or the like using chemicals. Etching is performed to corrode a material in a given pattern while a semiconductor is surface-polished and precisely processed, and in recent years, dry etching that does not use etching liquid has been more widely used in the semiconductor industry.

Dry etching refers to a method of performing etching in a gaseous system. Plasma etching is representative of dry etching, and the present invention relates to the technology regarding the dry etching.

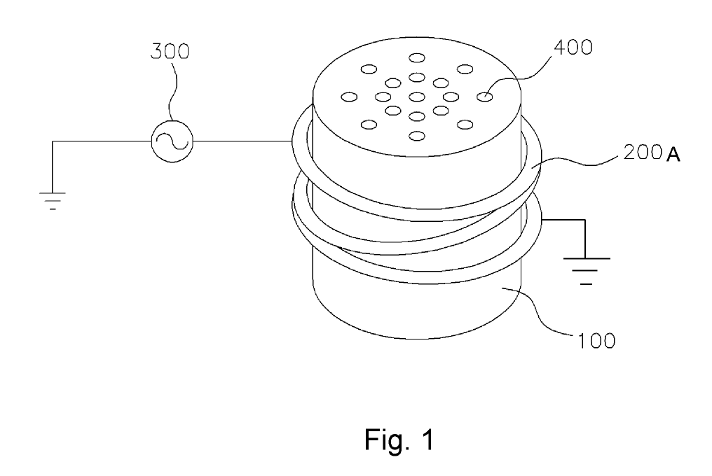

Specifically, the present disclosure relates to providing plasma ions of high density by specifying the form of a plasma chamber and an excitation coil disposed about the chamber and applying high frequency RF electric power thereto, so as to double the semiconductor processing performance and productivity compared to conventional dry etching devices. FIG. 1 illustrates a perspective view of a VHF Z-coil plasma source according to an embodiment of the present invention. The source for generating and injecting plasma using inductively coupled plasma (ICP) includes a chamber 100 for receiving process gas to generate plasma and inject the plasma, a Z-shaped coil 200A wound on the chamber in two horizontal turns of a conductor, and a high frequency RF power source 300 for applying high frequency RF power of 40 MHz to 120 MHz to the coil to generate the plasma. In the embodiment of FIG. 1, the two horizontal turns are interconnected by an inclined portion of conductor spanning approximately 180° about the chamber 100.

The chamber 100 of the present disclosure functions to generate plasma using a process gas for a dry etching process and inject the generated plasma onto a wafer 510. The form of the chamber 100 may be variously configured but is preferably cylindrical.

The size of the chamber 100 may be miniaturized for multiplication within a dry etching process. Specifically, the diameter of the chamber 100 may range from 5 cm to 10 cm and the height of the chamber 100 may range from 10 cm to 15 cm.

However, it is apparent that the detailed dimensions of the chamber 100 regarding the diameter and height may be changed as necessary or preferred, and it is preferable that the chamber 100 be formed of at least one of ceramics, quartz, SiC, and sapphire.

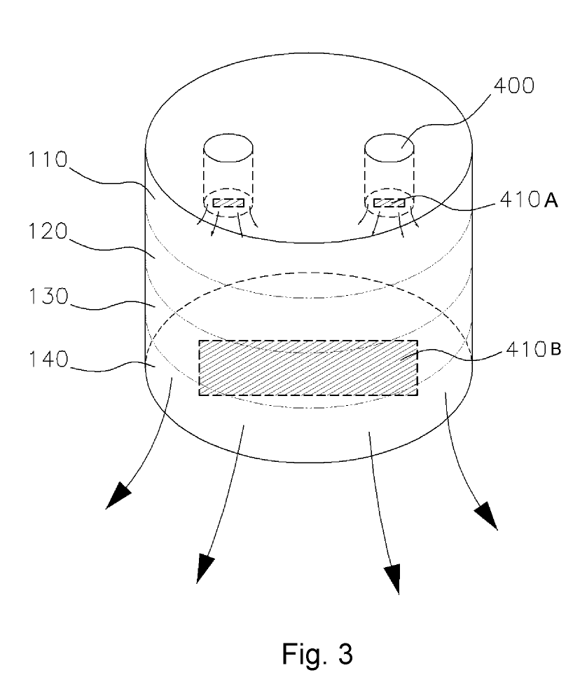

The chamber 10 is vertically partitioned from the top down into a mixing zone 110 for mixing a process gas, a generation zone 120 for generating plasma, an acceleration zone 130 for accelerating plasma, and a diffusion zone 140 for diffusing plasma. FIG. 3 illustrates a projective perspective view of a chamber according to an embodiment of the present disclosure, and it can be seen that the chamber 100 is divided into four zones as described above.

A process gas, supplied through one or more supply pipes 400, is mixed in the mixing zone 110. Plasma is generated using the process gas in the generation zone 120. The generated plasma is accelerated in the acceleration zone 130. The plasma is diffused in the diffusion zone 140 and discharged from the chamber 100.

The process gas may include CHF₃, C₄F₈, and CH₂F₂ according to the requirements for the process gas. CO₂ may be added in order to provide CO and O species for polymerization and oxidation.

An ICP type plasma source uses a coil to generate plasma within a chamber. The coil 200A of 2 5 the present disclosure is a Z-shaped coil wound on the chamber in two turns, in which the first turn surrounds an outside of the generation zone 120 of the chamber to contribute to generation of plasma and the remaining second turn surrounds an outside of the acceleration zone 130 of the chamber to contribute to acceleration of plasma.

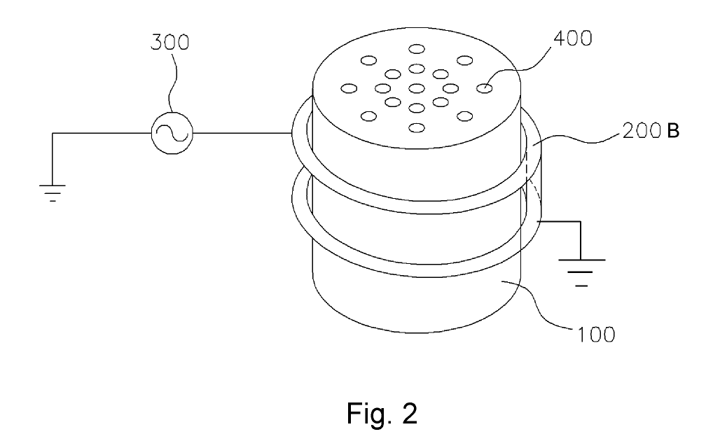

As can be seen in FIG. 1, the coil 200A may have a “Z” shape in which the first horizontal turn and the second horizontal turn are connected to each other by a diagonal portion of conductor. As can be seen in FIG. 2, illustrating a perspective of another embodiment of the present disclosure, a coil 200B may have a “g” shape such that the first horizontal turn and the second horizontal turn are connected to each other by a vertical conductor spanning the shortest distance between the first and second turns.

According to the present disclosure, high frequency RF electric power supplied by the power source 300 is applied to the coil to generate plasma. High frequency RF electric power of 40 MHz to 120 MHz is applied to generate plasma ions of high density as compared to the currently practiced RF electric power of 13.56 MHz or 27.12 MHz. The opposite end of the coil, adjacent to the acceleration zone 130, is connected to ground.

It was identified through experimentation that plasma of a high density is generated in the chamber 100 by applying such high frequency RF electric power from the power source 300 at 60 MHz, and RF electric power of a desired frequency within the frequency range can be applied if necessary.

Meanwhile, one or more supply pipes 400 for supplying a process gas are connected to an upper, mixing portion of the chamber 100, and FIGS. 1 and 2 illustrate that seventeen supply pipes are connected thereto, though the number of the supply pipes is exemplary and is not limited to seventeen. It is preferable that the number of supply pipes be a minimum of 1 to a maximum of 30, depending in part upon the dimensions of the chamber.

Upper diffusion plates 410A corresponding to the number of the supply pipes 400 are disposed at a lower portion of the mixing zone 110, each in vertical registration with the lower extent of the respective supply pipe. At least one lower diffusion plate 410B is also disposed in the diffusion zone 140.

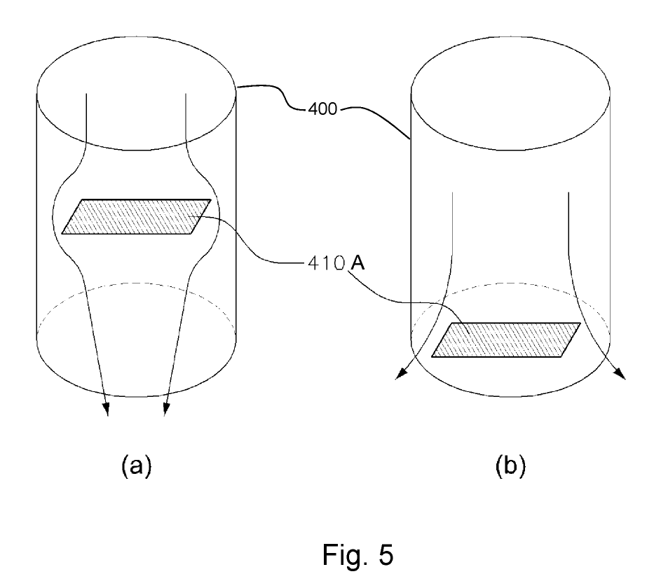

The diffusion plates 410A, 410B are oriented such that a process gas or plasma is not linearly, vertically diffused, but rather is discharged radially and more widely. FIG. 5 provides an exemplary view of the principle of the diffusion plate of the present disclosure.

First, if the diffusion plate 410A is spaced apart from a discharge opening of a pipe 400 through which a fluid flows and is located in the interior of the supply pipe 400 as illustrated in part (a) of FIG. 5, the flow of the fluid is changed as indicated by arrows and the fluid is discharged at the discharge opening of the pipe while gathering towards the center of the supply pipe 400.

However, if the diffusion plate 410A is located on the same plane as the discharge opening of the pipe 400 through which the fluid flows as illustrated in part (b) of FIG. 5, the flow of the fluid is discharged in an outward diffusion direction as indicated by the arrows.

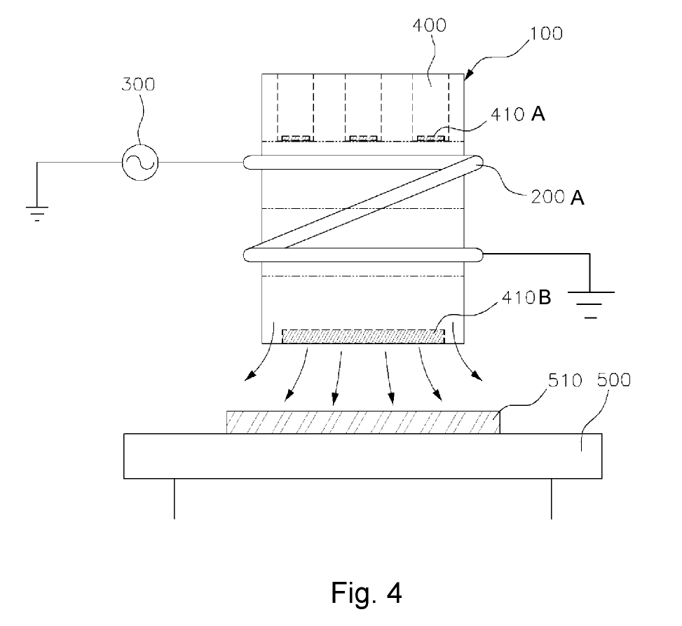

If one discharge pipe for the plasma discharged to the outside of the chamber 100 in the diffusion zone 140 is formed, one diffusion plate 410B is disposed in the diffusion zone, as illustrated in FIG. 4. However, if several discharge pipes are provided, diffusion plates corresponding to the number of the discharge pipes may be individually disposed therein.

Due to the disposition of the diffusion plates 410A within the lower extent of the gas pipes 400, a process gas is widely spread out from the mixing zone 110 to the generation zone 120 to improve the plasma generation efficiency, and plasma may be injected in a widely spread out pattern towards the wafer 510 disposed below the diffusion zone 140.

It is preferable that the diffusion plates 410A, 410B are formed of at least one of ceramics, quartz, silicon carbide, sapphire, and aluminum.

The plasma of a high density formed and injected by the illustrated configurations reaches a chuck 500 spaced below the chamber 100 and an upper surface of a semiconductor wafer 510 disposed on the chuck 500 for performing a dry etching process.

It is preferable that a distance between the chamber 100 and the semiconductor wafer 510 ranges from 3 cm to 10 cm for the efficiency of the process, and it is preferable that the length of the chuck 500 ranges from 20 cm to 40 cm.

In order to help understanding of the present disclosure, FIG. 4 illustrates a projective front view of the VHF Z-coil plasma device according to an embodiment of the present disclosure. As described above, the chamber is 100 partitioned into the mixing zone 110, the generation zone 120, the acceleration zone 130, and the diffusion zone 140, and the coil 200 is wound on the generation zone and the acceleration zone.

The high frequency RF power source 300 applies power to the coil 200A to generate plasma in the chamber 100 and the plasma is injected to a lower portion of the chamber. The chuck 500 and the semiconductor wafer 510 positioned thereon are disposed below the chamber such that a dry etching process is performed using the plasma.

As a result, according to the present disclosure, a coil having a specific shape is coupled to the chamber for generating plasma and RF electric power of a frequency that is higher than that of an existing plasma device is applied thereto, so that plasma ions of a high density can be generated and used in a dry etching process even at a low power.

In addition, according to the present disclosure, by specifically arranging diffusion plates in the interior of the chamber and thus efficiently diffusing the process gas and plasma, an efficiency of the dry etching process can be further improved.

Although the present disclosure has been described in relation to a detailed embodiment thereof, the illustrated embodiment is merely exemplary and the present disclosure is not limited thereto. Those skilled in the art to which the present disclosure pertains can change or modify the described embodiment without departing from the scope of the present disclosure, and various changes and modifications can be made in the technical spirit of the present disclosure and the equivalents of the claims.

What is claimed is:

1. A Very High Frequency (VHF) Z-coil plasma source for generating and injecting plasma using Inductively Coupled Plasma (ICP), the VHF Z-coil plasma device comprising:
a chamber for receiving a process gas for the generation of plasma and for injecting the generated plasma;
a Z-shaped coil wound on the chamber in two horizontal, interconnected conductor turns; and
a high frequency RF power source for generating electric power of 40 MHz to 120 MHz to be applied to the Z-shaped coil to generate the plasma from the process gas within the chamber.

2. The VHF Z-coil plasma source of claim 1, wherein the chamber comprises in vertical alignment from the top down:
a mixing zone for mixing the process gas;
a generation zone for generating the plasma upon excitation of the process gas by the electric power applied to the Z-shaped coil;
an acceleration zone for accelerating the generated plasma; and
a diffusion zone for diffusing the accelerated plasma.

3. The VHF Z-coil plasma source of claim 2, wherein the first conductor turn of the coil is disposed about the generation zone and the second conductor turn is disposed about the acceleration zone.

4. The VHF Z-coil plasma source of claim 2, wherein one or more diffusion plates for efficiently diffusing the process gas before and after plasma generation are disposed at lower portions of the mixing zone and the diffusion zone.

5. The VHF Z-coil plasma source of claim 4, wherein the diffusion plate is formed of at least one of ceramics, quartz, silicon carbide (SiC), sapphire, and aluminum.

6. The VHF Z-coil plasma source of claim 1, wherein the coil has a vertical conductor interconnecting the first and second conductor turns.

7. The VHF Z-coil plasma source of claim 1, wherein one or more supply pipes for supplying the process gas are connected to an upper portion of the chamber.

8. The VHF Z-coil plasma source of claim 1, wherein the chamber has a cylindrical shape.

9. The VHF Z-coil plasma source of claim 8, wherein a diameter of the chamber is 5 cm to 10 cm.

10. The VHF Z-coil plasma source of claim 8, wherein a height of the chamber is 10 cm to 15 cm.

11. The VHF Z-coil plasma source of claim 1, wherein the chamber is formed of at least one of ceramics, quartz, silicon carbide (SiC) and sapphire.

12. The VHF Z-coil plasma source of claim 1, further comprising a chuck disposed beneath the chamber for receiving a semiconductor wafer thereon, whereby the distance between a wafer disposed on the chuck and the chamber is 3 cm to 10 cm.

13. The VHF Z-coil plasma source of claim 12, wherein a length of the chuck is 20 cm to 40 cm.
